(19) United States
(12) Patent Application Publication
(10) Pub. No.: US 2014/0241456 A1
(43) Pub. Date: Aug. 28, 2014

(54) COMMUNICATION DEVICE, COMMUNICATION SYSTEM, AND COMMUNICATION METHOD

(71) Applicant: RENESAS ELECTRONICS CORPORATION, Kawasaki (JP)

(72) Inventors: Kiyoshi YANAGISAWA, Kanagawa (JP); Osamu INAGAWA, Kanagawa (JP)

(73) Assignee: RENESAS ELECTRONICS CORPORATION, Kawasaki (JP)

(21) Appl. No.: 14/185,294

(22) Filed: Feb. 20, 2014

(30) Foreign Application Priority Data
Feb. 28, 2013 (JP) 2013-038228

(51) Int. Cl. H04B 1/10; H03G 3/20

(52) U.S. Cl. CPC H04B 1/10; H03G 3/20
USPC 375/285; 375/345

(57) ABSTRACT

A communication device includes: an amplifier (62) arranged to amplify a reception signal received from one of the plurality of terminals; a first demodulation unit (26) arranged to demodulate a first frame transmitted using a first communication method operable to communicate when CNR is smaller than 0 dB; a second demodulation unit (27) arranged to demodulate, in parallel with the first demodulation unit demodulating the first frame, a second frame transmitted using a second communication method having a rate higher than a rate of the first communication method at a frequency band same as a frequency band used for the first communication method; and a gain controller (64) arranged to adjust a gain of the amplifier in accordance with a detection outcome of a preamble included in the first frame and the second frame.

### CROSS-REFERENCE TO RELATED APPLICATIONS

This application is based upon and claims the benefit of priority from Japanese patent application No. 2013-038228, filed on Feb. 28, 2013, the disclosure of which is incorporated herein in its entirety by reference.

### BACKGROUND

The present invention relates to a communication device, and a communication method.

CSMA/CA (Carrier Sense Multiple Access/Collision Avoidance) has been available as a communication method to avoid collisions of frames using the same frequency (http://ja.wikipedia.org/wiki/CSMA/CA or http://en.wikipedia.org/wiki/CSMA/CA). According to CSMA/CA, a confirmation process is carried out prior to conducting a communication in order to determine whether there is a host presently communicating by conducting a test reception.

When a plurality of clients share a common line, and no other client is conducting a communication, one starts its communication. When a host is present during a carrier sensing phase, it is highly possible that a collision will occur if a transmission is attempted simultaneously as the end of a communication. Thus, when an end of a transmission by a host is detected, a waiting period of random length is assigned prior to starting another transmission.

### SUMMARY

The present inventors have found the following problem. According to the above stated method, there is a problem that one host is not allowed to conduct a communication when another host is conducting another communication. For example, there are occasions where it is necessary, due to a line deterioration, to conduct a communication using a robust frame having a low bit rate. In such occasions in which the low bit rated frame is transmitted, the speed of the entire network may be slowed down due to a long duration of an occupied line.

Other problems and novel features will become obvious from the following description and the accompanying drawings of the present application.

According to a first aspect of the embodiment, a communication device includes a first demodulation unit arranged to demodulate a first frame transmitted using a first communication method operable to communicate when CNR is smaller than 0 dB; and a second demodulation unit arranged to demodulate, in parallel with the first demodulation unit demodulating the first frame, a second frame transmitted using a second communication method having a rate higher than a rate of the first communication method at a frequency band same as a frequency band used for the first communication method; wherein the communication device adjusts a gain of an amplifier in accordance with a detection outcome of a preamble included in the first frame and the second frame.

Note that a device according to the above stated example may be valid as the present embodiment when the same takes a form of a method, a system, or a program for allowing a computer to execute a process, which is otherwise executed by the device or a portion thereof, and a communication system which includes the device.

According to the example described above, it is possible to provide a high-performance communication device, a communication system, and a communication method.

### BRIEF DESCRIPTION OF THE DRAWINGS

The above and other aspects, advantages and features will be more apparent from the following description of certain embodiments taken in conjunction with the accompanying drawings, in which:

FIG. 1 is a schematic diagram illustrating a method to avoid a frame collision;

FIG. 2 is a schematic diagram illustrating an occupation of the line due to a frame;

FIG. 3 is a schematic diagram illustrating signal and noise levels in a robust communication and an ordinary communication;

FIG. 4 is a schematic diagram illustrating a communication method according to embodiments;

FIG. 5 is a schematic block diagram illustrating a configuration of a communication system;

FIG. 6 is a schematic block diagram illustrating the configuration of a communication device according to a first embodiment;

FIG. 7 is a schematic diagram illustrating a process procedure of the communication device according to the first embodiment;

FIG. 8 is a schematic block diagram illustrating the configuration of a communication device according to a second embodiment;

FIG. 9 is a schematic diagram illustrating a process procedure of the communication device according to the second embodiment;

FIG. 10 is a schematic diagram illustrating a process procedure of the communication device according to a third embodiment; FIG. 11 is a schematic block diagram illustrating the configuration of a communication device according to a fourth embodiment;

FIG. 12 is a schematic diagram illustrating a process procedure of the communication device according to the fourth embodiment;

FIG. 13 is a schematic diagram illustrating a process procedure of the communication device according to the fourth embodiment;

FIG. 14 is a schematic block diagram illustrating a first example of the reception quality judgment unit;

FIG. 15 is a schematic block diagram illustrating a second example of the reception quality judgment unit;

FIG. 16 is a schematic block diagram illustrating a third example of the reception quality judgment unit;

FIG. 17 is a schematic block diagram illustrating the configuration of a communication device when the communication device communicates with a plurality of terminals; and

FIG. 18 is a schematic block diagram illustrating a configuration of a communication device according to an embodiment.

### DETAILED DESCRIPTION

For the clarity of the description, the following description and drawings may be simplified and abbreviated in an appropriate manner. Further, each element, which is depicted in the drawings as function blocks arranged to execute various processes, may be configured, as hardware, by a CPU, memory, or a circuit in another form, or, as software, by a program loaded onto a memory. Accordingly, these function blocks may be realized in a form of hardware, software, or a combination of the two as commonly understood by persons having ordinary skill in the art, and are not be limited to any specific form. Further, it is to be noted that the elements having substantially the same features depicted in the drawings will be assigned the same reference numerals, and the description thereof will not be repeated as appropriate.

Further, the program may be stored by using various types of non-transitory computer readable medium, and supplied to computers. The non-transitory computer readable medium includes various types of tangible storage medium. Examples of the non-transitory computer readable medium include a magnetic recording medium (such as a flexible disk, a magnetic tape, and a hard disk drive), a magneto-optic recording medium (such as a magneto-optic disk), a CD-ROM (Read Only Memory), a CD-R, and a CD-R/W, and a semiconductor memory (such as a mask ROM, a PROM (Programmable ROM), an EPROM (Erasable PROM), a flash ROM, and a RAM (Random Access Memory)). Further, the program may be supplied to computers by using various types of transitory computer readable media. Examples of the transitory computer readable media include an electrical signal, an optical signal, and an electromagnetic wave. The transitory computer readable media may be used to supply programs to computer through a wire communication path such as an electrical and an optical fiber, or wireless communication path.

(Outline)

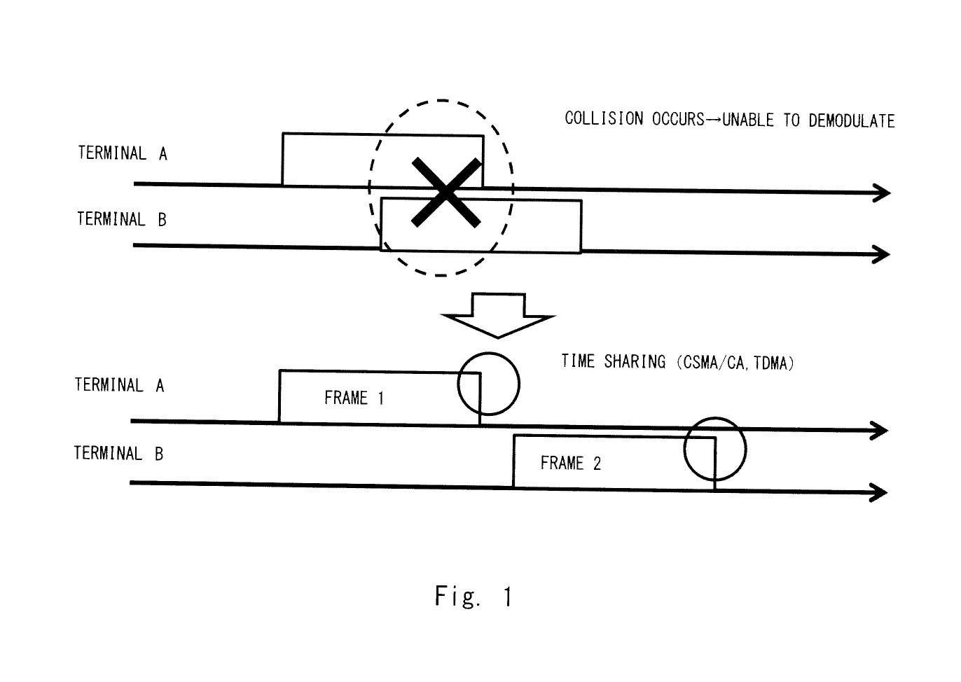

An outline of the communication method according to the present example will be described. FIG. 1 is a schematic diagram illustrating a method to avoid a frame collision. Note that in the description herein, a method in which a line is shared, such as PLC or wireless, will be described. In a communication system in which a line is shared, when a frame collision occurs between a frame transmitted by a terminal A and a frame transmitted by a terminal B, each frame acts as a noise to the other frame and interferes with the frames. Consequently, the frame at a receiving end will not be demodulated. In order to prevent the occurrence of such an issue, time sharing is usually used by a method such as CSMA/CA or TDMA (Time Domain Multiple Access).

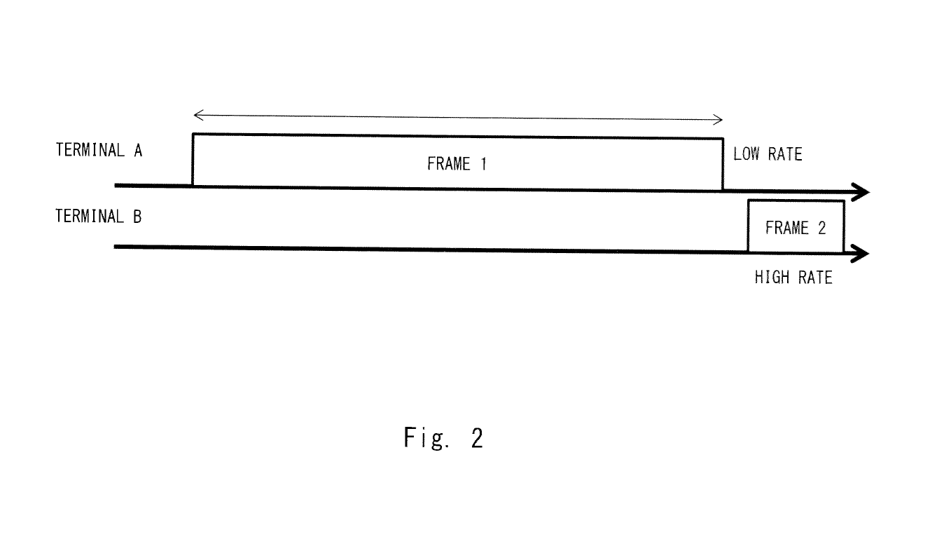

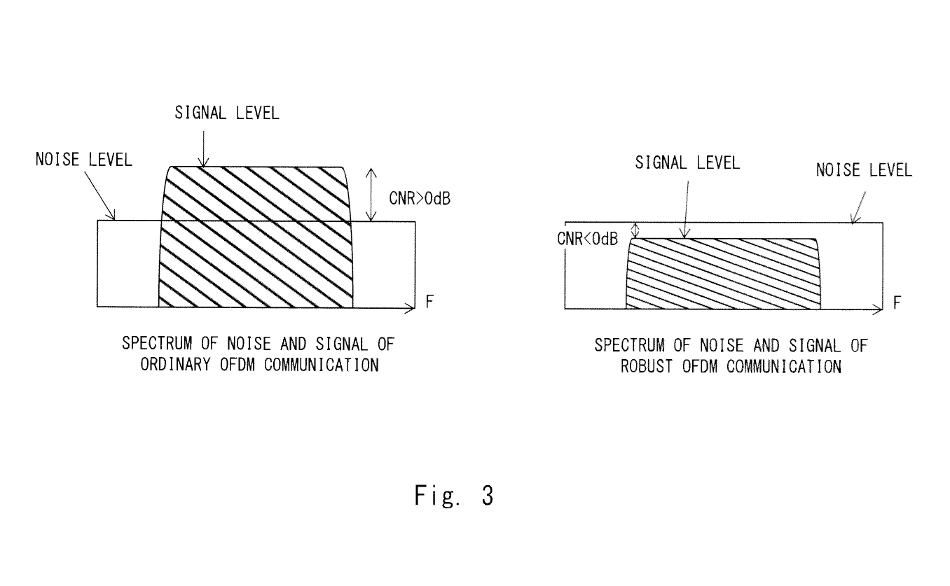

Therefore, only one frame is transmitted at a same time, meaning that after a transmission of a frame 1 by a terminal A is completed, a frame 2 is transmitted by a terminal B. During such transmission, one of the frames occupies the line. As shown in FIG. 2, the low rated frame 1, whose bit rate is slow, occupies the line for a long period of time. Since the terminal A transmits the frame 1 having a low rate, the terminal B is not able to transmit the frame 2 having a high rate for a long time. Consequently, the entire network's transmission rate is lowered, and thus the performance of the network deteriorates.

On the other hand, the applicant of the present invention provides an OFDM (Orthogonal Frequency Divisional Multiplexing) method which allows a robust communication when CNR (Carrier to Noise Ratio) is low for PLC, or the like, having a large noise or attenuation (Japanese Patent Application No. 2012-105866). For example, as shown in FIG. 3, in an ordinary OFDM communication, a signal level is higher than a noise level, whereas in a robust communication, the signal level is lower than the noise level. Note that in FIG. 3 the horizontal axis indicates the frequency while the vertical axis indicates the signal level. For example, by providing redundancy to data, which is to be transmitted, it becomes possible to carry out a communication while the CNR is smaller than 0 dB. To be more specific, when transmission data is interleaved, by providing redundancy to the data, the noise proof property thereof will be improved. Consequently, the data will be transmitted while the CNR is smaller than 0 dB (i.e., CNR<0 dB). In other words, the greater the redundancy provided to data is, the lower the transmission rate becomes.

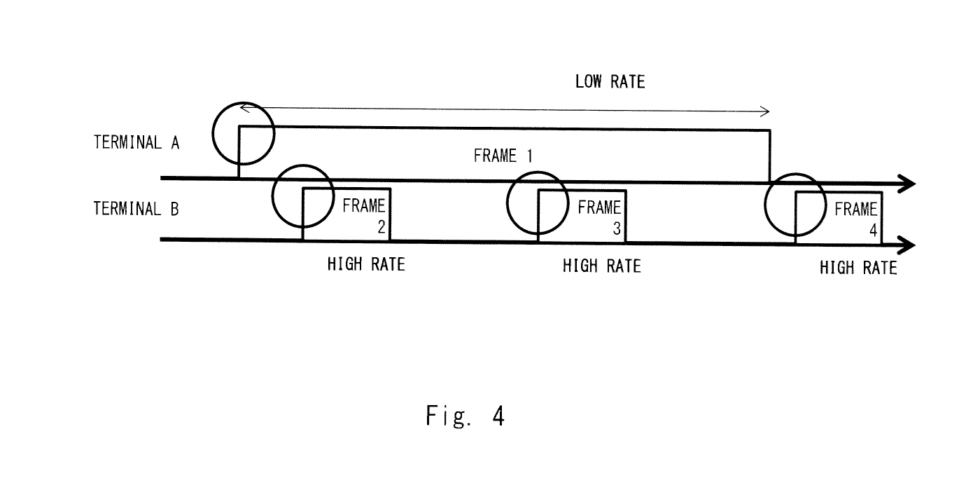

In a communication method having a good noise proof property, even when frames collide, each collided frame may be demodulated. For example, as shown in FIG. 4, frames 2 to 4, each having a high rate, are collided, to a tolerable extent, with a frame 1 of a first communication method having a high noise proof property. That is, while the frame 1 of the first communication method being transmitted, the frames 2 to 4 of a communication method having a high rate are actively collided. By such operation, it becomes possible for the both of the frames to be received simultaneously, thereby increasing the transmission capacity. While the frame 1 having the low rate is being transmitted, the frames 2 to 4 each having the high rate are received.

In the reception of the low rated frame 1, the high rated frames 2 to 4 become a noise to the frame 1. However, the low rated frame 1 is provided with a redundancy. Therefore, even if the high rated frames 2 to 4 are collided with the frame 1 for a certain period of time, the low rated frame 1 is demodulated.

In the reception of the high rated frames 2 to 4, the low rated frame 1 becomes a noise to the high rated frames 2 to 4. However, as shown in FIG. 3, the robust communication method is used mainly when the signal level is lower than the noise level. That is to say, since the CNR is smaller than 0 dB (i.e., CNR<0 dB), the signal level of the low rated frame 1 is lower than the noise level. On the other hand, when the signal level of the high rated frames 2 to 4 is adequately higher than the noise level, a communication method using a high rate is used. Even when the frame 1 becomes a noise, the high rated frames 2 to 4 are received at a high CNR. Even when a high rated frame 1 is collided with the low rated frames 2 to 4, the high rated frame 1 can be demodulated. Accordingly, the performance of the entire network will be improved.

### First Embodiment

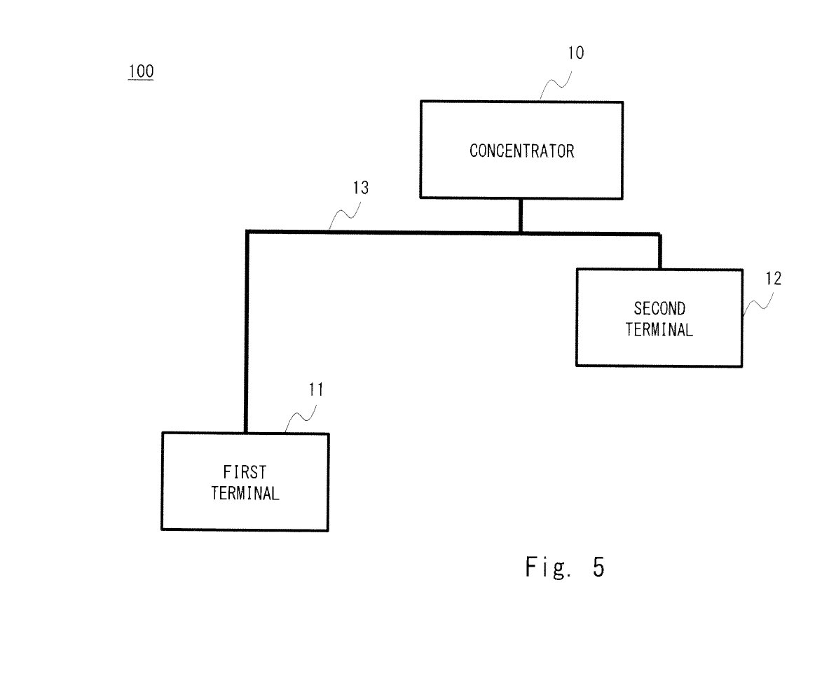

Hereinafter, a communication system according to a present embodiment will be described. FIG. 5 is a schematic block diagram illustrating a configuration of the communication system according to the present embodiment. A communication system 100 is a network including a concentrator 10, a first terminal 11, a second terminal 12, and an electric power line 13. The communication system 100 according to the present embodiment is a power line carrier communication utilizing the electric power line 13 as a communication line thereof.

The concentrator 10, which is a communication device, is connected to the first terminal 11 and the second terminal 12 via the electric power line 13. It is to be noted that although FIG. 5 shows only two terminals (i.e., the first terminal 11 and the second terminal 12), the number of the terminals is not limited thereto. That is, the number of the terminals may be 3 or greater.

The concentrator 10 is operable to communicate with the first terminal 11 and the second terminal 12. That is, the concentrator 10 transmits signals to the first terminal 11 and the second terminal 12, and receives signals from the first terminal 11 and the second terminal 12 via the electric power line 13. For example, the concentrator 10 modulates data, which is transmitted via a predetermined communication method, and transmits the modulated data to the first terminal 11 and the second terminal 12. The first terminal 11 and the second terminal 12 each receive frames via the electric power line 13. The concentrator 10 receives the frames transmitted by the first terminal 11 and the second terminal 12. The concentrator 10 demodulates the frame via a predetermined communication method. Note that the concentrator 10 may only include a receiving capability. Further, note that the OFDM method, or the like, may be used for modulation and demodulation.

The first terminal 11 is arranged farther from the concentrator 10, whereas the second terminal 12 is arranged nearer to the concentrator 10, relatively. That is, the communication range between the first terminal 11 and the concentrator 10 is greater than the communication range between the second terminal 12 and the concentrator 10. Since the greater the communication range, the greater the attenuation, the signal, which is transmitted to and received by the concentrator 10 and the first terminal 11, includes, relatively speaking, a greater attenuation. On the other hand, the signal, which is transmitted to and received by the concentrator 10 and the second terminal 12, includes, relatively speaking, a smaller attenuation.

Accordingly, for the communication between the concentrator 10 and the first terminal 11, a robust frame having a low rate is used. In other words, for the communication between the concentrator 10 and the first terminal 11, since the redundancy is provided to data, the length of the frame becomes long. On the other hand, for the communication between the concentrator 10 and the second terminal 12, a frame having a high rate and whose CNR is high is used. In other words, for the communication between the concentrator 10 and the second terminal 12, the length of frames is short.

Hereinafter, the communication method used for the communication between the concentrator 10 and the first terminal 11 will be referred to as a first communication method; and the communication method used for the communication between the concentrator 10 and the second terminal 12 will be referred to as a second communication method. Since the first communication method includes a large attenuation, a robust frame having a low rate (hereinafter, a first frame) will be used therein. Further, since the second communication method includes a small attenuation, a frame having a high rate and a high CNR (hereinafter, a second frame) will be used therein. Note that, the first communication method and the second communication method use the same frequency band. In other words, the first communication method and the second communication method transmit and receive frames by each placing data on a carrier of the same frequency.

The first communication method is used when CNR (i.e., Carrier to Noise Power Ratio) is smaller than 0 dB. On the other hand, the second communication method is used when CNR is greater than 0 dB. Note that the first communication method and the second communication method may use completely the same frequency, or the same frequency only for a portion of the carriers. That is, only a certain portion of the carriers needs to have the common frequency. For example, the first communication method and the second communication method each modulate and demodulate data via the OFDM method utilizing the common frequency.

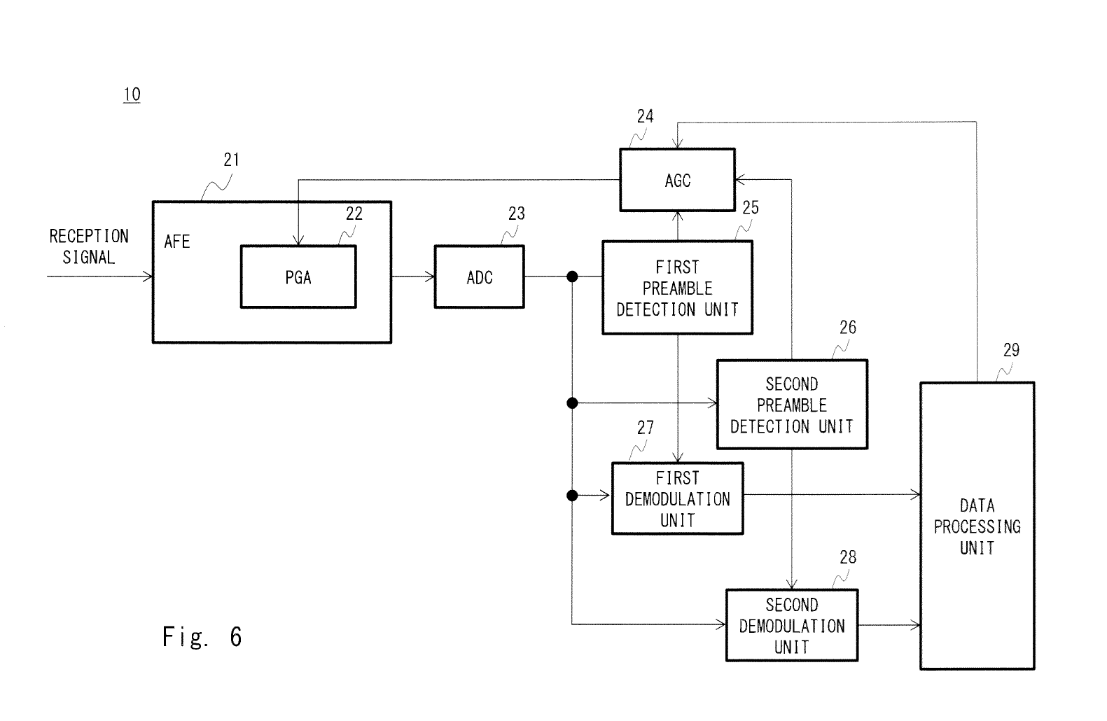

Next, a configuration of the concentrator 10 will be described with reference to FIG. 6. FIG. 6 is a schematic block diagram illustrating the configuration of the concentrator 10. The concentrator 10 includes an AFE (Analog Front End) 21, a PGA (Programmable Gain Amplifier) 22, an ADC (Analog Digital Converter) 23, an AGC (Automatic Gain Control) 24, a first preamble detection unit 25, a second preamble detection unit 26, a first demodulation unit 27, a second demodulation unit 28, and a data processing unit 29. Note that although in the description herein, the concentrator 10 includes only the features for receiving data, the concentrator 10 may also include features for transmitting data.

The AFE 21 receives a reception signal propagated via the electric power line 13. The AFE 21 includes the PGA 22. The PGA 22 amplifies the received signal by a predetermined gain. Then, the AFE 21 outputs the received signal, which is amplified by the PGA 22, to the ADC 23. The ADC 23 carries out an AD conversion of the received signal. Here, the received signal, which is digitalized by the ADC 23, will be referred to as a digital received signal.

The ADC 23 outputs the digital received signal to the first preamble detection unit 25, the second preamble detection unit 26, the first demodulation unit 27, and the second demodulation unit 28. The first preamble detection unit 25 and the second preamble detection unit 26 each detect a preamble included in the digital received signal. The first preamble detection unit 25 detects a preamble included in a frame, which is modulated by the first communication method. The second preamble detection unit 26 detects a preamble included in a frame, which is modulated by the second communication method. Note that a preamble is arranged at a front end of a frame.

For example, when the first terminal 11 transmits, via the first communication method, a low rated and robust first frame, the first preamble detection unit 25 detects a preamble included in the first frame. In a similar manner, when the second terminal 12 transmits, via the second communication method, a high rated second frame having a high CNR, the second preamble detection unit 26 detects a preamble included in the second frame. The first preamble detection unit 25 and the second preamble detection unit 26 each output to the AGC 24 a detection signal indicating that a frame has been detected.

The AGC 24 adjusts a gain of the PGA 22 such as to make the levels of the received signal, inputted to the ADC 23, constant. The AGS 24 lowers the gain of the PGA 22 upon receiving the detection signal. Consequently, the AGC 24 lowers the gain of the PGA 22 while the frame being received. Then, when the frame reception is complete and the concentrator 10 is in a state in which it is not receiving a frame, the AGS 24 raises the gain. In this manner, the AGS 24 adjusts the gain of the PGA 22 in accordance with the detection signal. Accordingly, it becomes possible to amplify a header and/or payload, or the like, which follows the preamble of the frame, by an appropriate gain, and carry out the demodulation process appropriate to the frame. Note that the gain with respect to the first frame of the first communication method and the gain with respect to the second frame of the second communication method may be the same as or different from one another. For example, during a reception of a frame, AGS 24 controls the gain such that the signal levels inputted to the ADS 23 are even.

Further, the first preamble detection unit 25 outputs the detection signal to the first demodulation unit 27. The first demodulation unit 27 demodulates the digital received signal upon receiving the detection signal. The first demodulation unit 27 demodulates the first frame in accordance with the first communication method. Consequently, it becomes possible for the first demodulation unit 27 to demodulate the low rated and robust first frame.

In a similar manner, the second preamble detection unit 26 outputs the detection signal to the second demodulation unit 28. The second demodulation unit 28 demodulates the digital received signal upon receiving the detection signal. The second demodulation unit 28 demodulates the second frame in accordance with the second communication method. Consequently, it becomes possible for the second demodulation unit 28 to demodulate the high rated second frame.

The first demodulation unit 27 acquires first demodulated data by demodulating the first frame. The first demodulation unit 27 outputs the first demodulated data to the data processing unit 29. The second demodulation unit 28 acquires second demodulated data by demodulating the second frame. The second demodulation unit 28 outputs the second demodulated data to the data processing unit 29. The data processing unit 29 carries out a data processing to the first demodulated data and the second demodulated data. For example, the data processing unit 29 carries out a frequency/time de-interleave process, P/S conversion, and decoding, or the like. Consequently, the data processing unit 29 is operable to acquire data included in the received signal. Note that since the process carried out by the data processing unit 29 may be well known in the art, the description thereof will be omitted. The data processing unit 29 outputs a completion signal to the AGC 24 upon completing the process performing to the frame. As described above, AGC 24 adjusts the gain of the PGA 22 based on the completion signal. Consequently, in a state where no frame is being transmitted, the AGC 24 is operable to lower the gain of the PGA 22.

The first preamble detection unit 25 and the second preamble detection unit 26 operate in parallel. Further, the first demodulation unit 27 and the second demodulation unit 28 carry out the demodulation process in parallel. By virtue of such operation, it becomes possible to receive data even when the first terminal 11 and the second terminal 12 transmit respective frames simultaneously. That is, when the second preamble detection unit 26 detects the preamble of the second frame while the first demodulation unit 27 demodulates the first frame, the second demodulation unit 28 starts its demodulation process. Therefore, the first demodulation unit 27 and the second demodulation unit 28 are able to simultaneously carry out individual demodulation processes on respective frames.

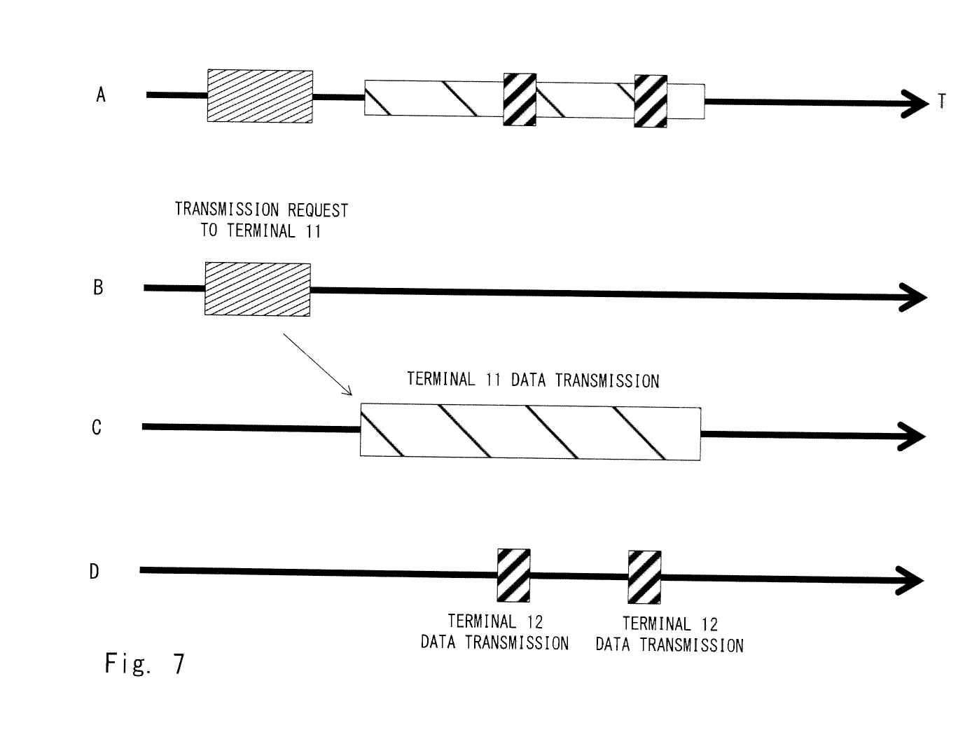

Hereinafter, the demodulation processes which are carried out in parallel by the second demodulation unit 28 and the first demodulation unit 27 will be described with reference to FIG. 7. In FIG. 7, A schematically illustrates a reception waveform of the concentrator 10, and B schematically illustrates a transmission waveform of the concentrator 10. Further, in FIG. 7, C illustrates a transmission waveform of the first terminal 11, and D illustrates a transmission waveform of the second terminal 12.

First, as shown by B in FIG. 7, the concentrator 10 transmits a transmission request to the first terminal 11 in accordance with the first communication method. Then, as shown by C in FIG. 7, the first terminal 11 transmits data. The first terminal 11, which transmits the data in accordance with the first communication method, transmits the low rated and highly robust first frame. Consequently, the length of the first frame is long. As shown by A in FIG. 7, the concentrator 10 receives the data from the first terminal 11. Note that in A in FIG. 7, the transmission request transmitted by the concentrator 10 goes around before being received. The first preamble detection unit 25 detects a preamble included in the first frame transmitted from the first terminal 11, and outputs the detection signal. Upon receiving the detection signal, the first demodulation unit 27 starts the process of demodulation of the first frame which is transmitted from the first terminal 11.

While the first terminal 11 transmits the data, the second terminal 12 transmits data. As shown in A in FIG. 7, the concentrator 10 receives the data from the second terminal 12. As described above, the first preamble detection unit 25 and the second preamble detection unit 26 each detect the preamble in parallel, and the first demodulation unit 27 and the second demodulation unit 28 carry out the respective demodulation processes in parallel. That is, while the first frame is transmitted from the first terminal 11, the second preamble detection unit 26 detects a preamble included in the second frame transmitted from the second terminal 12. Once the second preamble detection unit 26 detects the preamble, the second preamble detection unit 26 outputs the detection signal. Upon receiving the detection signal, the second demodulation unit 28 starts the process of demodulation of the second frame which is transmitted from the first terminal 12.

Since the first frame includes the redundancy, even when the reception signal of the second frame becomes a noise to the first frame, the first demodulation unit 27 is operable to demodulate the first frame. That is, a period, in which the second frame is transmitted, is adequately shorter compared with the length of the first frame. Therefore, even when the second frame becomes a noise to the first frame, it becomes possible to carry out the demodulation process of the first frame, which includes the redundancy.

In the meantime, since the first frame is used when the CNR is smaller than 0 dB, even when the reception signal of the first frame becomes a noise to the second frame, the second demodulation unit 28 is operable to demodulate the second frame. That is, the signal level of the first frame is adequately low compared with the signal level of the second frame. Thus, it becomes possible to carry out the demodulation process of the second frame.

As described above, the second demodulation unit 28 carries out the demodulation process in parallel with the demodulation process carried out by the first demodulation unit 27. That is, the demodulation process of the first frame carried out by the first demodulation unit 27 and the demodulation process of the second frame carried out by the second demodulation unit 28 are carried out simultaneously. Consequently, an occupation period of the line will be shortened, thereby improving the transmission rate of the entire network. Therefore, since the concentrator 10 is operable to receive a plurality of frames in parallel, the performance of the entire network will be improved. In a multiple access communication, since robust frames are actively collided, to an appropriate extent, the transmission capacity of the network is improved.

### Second Embodiment

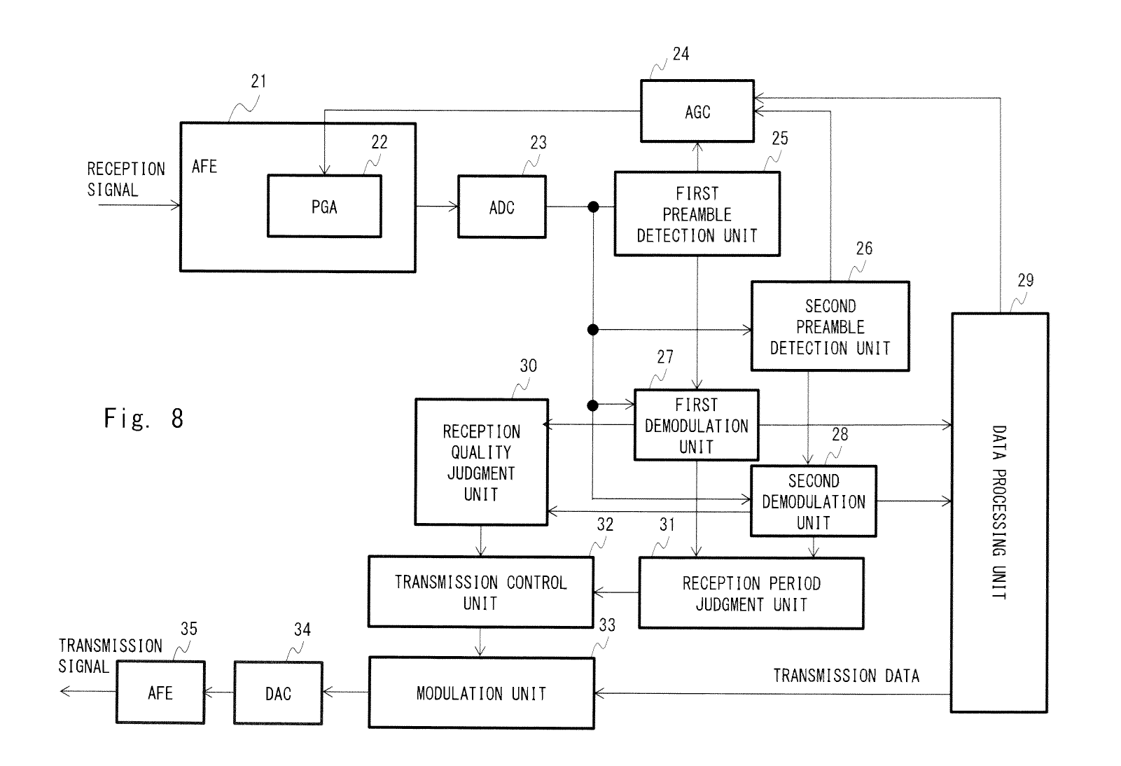

A communication device according to a present embodiment will be described with reference to FIG. 8. FIG. 8 is a schematic block diagram illustrating a configuration of the concentrator 10, which is a communication device. Note that since the configuration of the entire system according to the present embodiment is the same as that in the first embodiment, the portion of the second embodiment, which overlaps with what is already described in the first embodiment, will be omitted. Further, detail descriptions for the current embodiment the same as those for the first embodiment will be omitted as appropriate. For example, the descriptions concerning the AFE 21, the PGA 22, the ADC 23, the AGS 24, the first preamble detection unit 25, the second preamble detection unit 26, the first demodulation unit 27, the second demodulation unit 28, and the data processing unit 29 for the current embodiment will be omitted as they are the same as those for the first embodiment. The description concerning the reception demodulation processing for the current embodiment will be omitted as the process is the same as that for the first embodiment. Further, it is to be noted that like the concentrator in the first embodiment, in the concentrator 10 according to the current embodiment, the first demodulation unit 27 and the second demodulation unit 28 also carry out the demodulation process in parallel.

According to the present embodiment, the concentrator 10 includes, additionally to the configuration of the concentrator 10 illustrated in FIG. 6, a reception quality judgment unit 30, a reception period judgment unit 31, a transmission control unit 32, a modulation unit 33, a DAC (Digital Analog Converter) 34, and an AFE 35. Further, the concentrator 10 transmits data while receiving the low rated first frame.

The first demodulation unit 27 outputs demodulated data to the reception quality judgment unit 30 and the reception period judgment unit 31. The second demodulation unit 28 outputs demodulated data to the reception quality judgment unit 30 and the reception period judgment unit 31. The reception quality judgment unit 30 judges reception quality based on the demodulated data. The reception period judgment unit 31 judges a reception period based on the demodulated data. The reception period judgment data unit 31 judges reception quality by utilizing, for example, an LQI (Link Quality Indicator) value, which indicates the signal strength of the received signal. Note that the reception period judgment unit 31 may use an RSSI (Received Signal Strength Indicator) or an error rate, or the like, instead of the LQI value, or the combination of multiple indicators, to judge communication quality.

To be more specific, the reception period judgment unit 31 makes a judgment on a reception period of the first frame by utilizing header information, which is included in the first frame. That is, the reception period judgment unit 31 makes a determination as to whether or not the first frame is received. Then, the reception period judgment unit 31 outputs a judgment outcome to the transmission control unit 32. The reception quality judgment unit 30 makes a determination as to whether or not reception quality is above a predetermined value by comparing the reception quality of the first frame with a threshold value. Then, the reception quality judgment unit 30 outputs the judgment outcome regarding the reception quality to the transmission control unit 32.

The data processing unit 29 outputs transmission data to the modulation unit 33. The modulation unit 33 modulates the transmission data and outputs the modulated transmission data to the DAC 34. The DAC 34 carries out a DA conversion of the modulated transmission data. The DAC 34 outputs the transmission data, which is converted into analog data, to the AFE 35. The AFE 35 amplifies the analog transmission data with a predetermined gain. Then, the AFE 35 outputs the amplified transmission data as a transmission signal. For example, the transmission data is amplified such that the transmission signal is at a predetermined level. Then, the concentrator 10 outputs the transmission signal to the second terminal 12 via the electric power line 13.

The transmission control unit 32 controls the modulation process carried out by the modulation unit 33. That is, the transmission control unit 32 makes the modulation unit 33 carry out the modulation process when reception quality is above the predetermined level. On the other hand, when reception quality is below the predetermined level, the transmission control unit 32 controls so that the modulation unit 33 does not carry out the modulation process. That is, the modulation unit 33 is on standby until reception quality is above the predetermined level, and starts the modulation process once reception quality is at the predetermined level. Thus, the transmission control unit 32 controls the transmission process in accordance with reception quality.

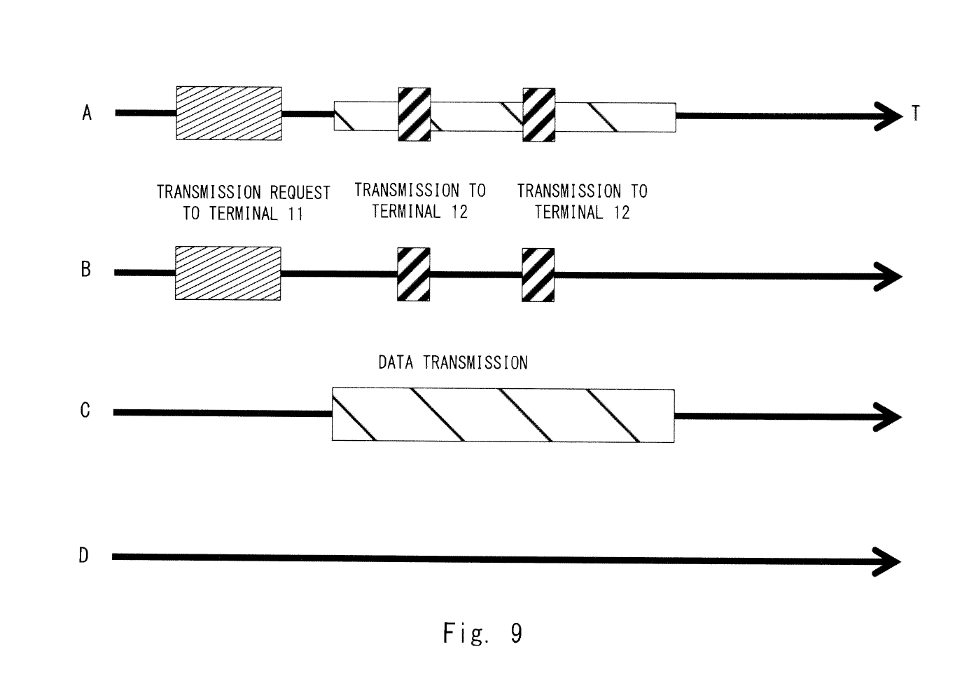

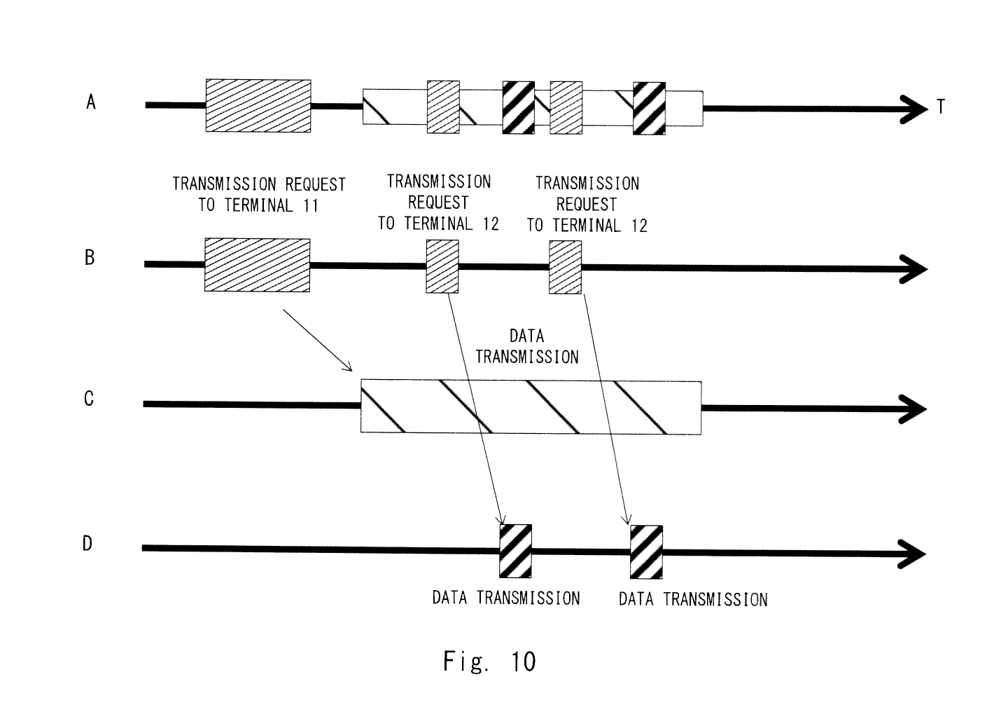

With reference to FIG. 9, the communication process of the present example will be described. In FIG. 9, A schematically illustrates a reception waveform of the concentrator 10, and B schematically illustrates a transmission waveform of the concentrator 10. Further, in FIG. 9, C illustrates a transmission waveform of the first terminal 11, and D illustrates a transmission waveform of the second terminal 12.

First, as shown by B in FIG. 9, the concentrator 10 transmits a transmission request to the first terminal 11. Then, as shown by C in FIG. 9, the first terminal 11 transmits data. The concentrator 10 receives the first frame transmitted by the first terminal 11. Then, the concentrator 10 transmits the data to the second terminal 12 when the reception quality of the first frame in the concentrator 10 is above the predetermined level. The concentrator 10 transmits, while receiving the first frame, a plurality of the second frames intermittently to the second terminal 12. Note that concentrator 10 transmits the high rated second frame having the high CNR to the second terminal 12.

As described above, since the first terminal 11 modulates the data by the first communication method, the first terminal 11 transmits the low rated and highly robust first frame. Accordingly, even when the second frame becomes a noise due to a wraparound, the concentrator 10 is operable to demodulate the first frame. Further, since the second frame includes the high CNR, the second terminal 12 is operable to demodulate the second frame. By virtue of such procedure, the concentrator 10 is operable to transmit data while receiving the first frame, thereby increasing the network capacity.

### Third Embodiment

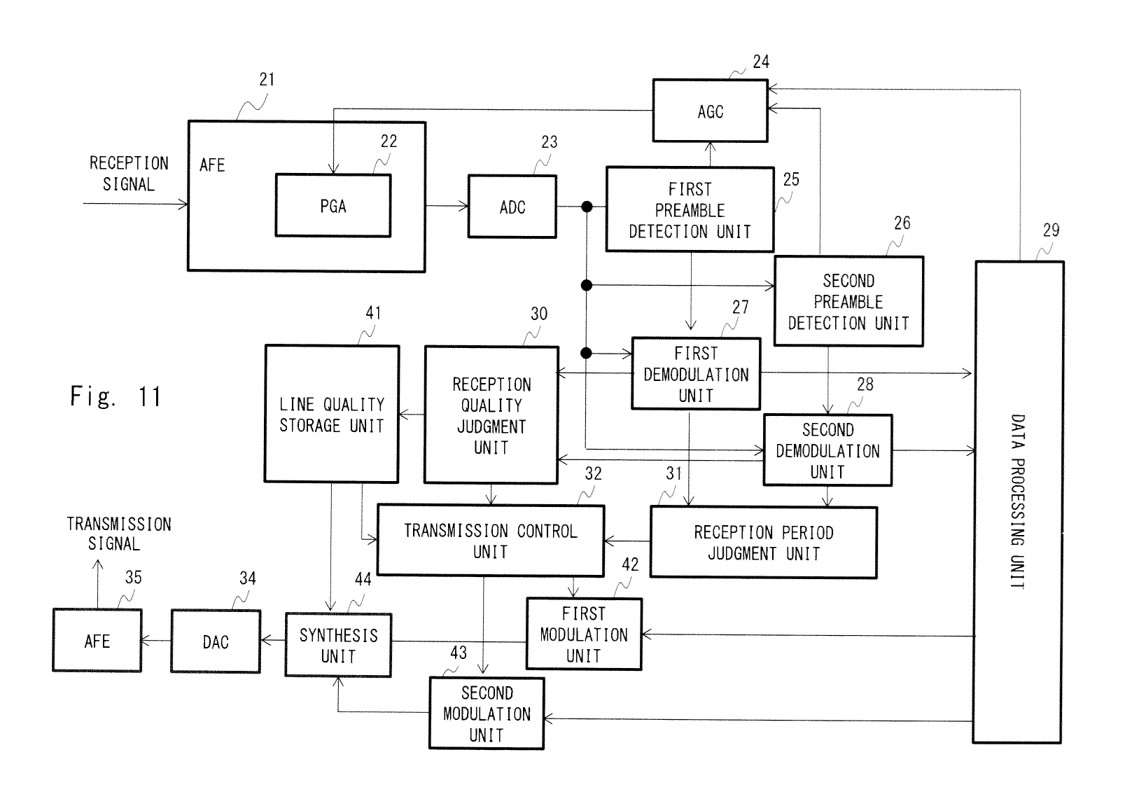

A communication device according to the present embodiment will be described with reference to FIG. 10. FIG. 10 is a schematic diagram illustrating a communication procedure according to a communication method. In FIG. 10, A schematically illustrates a reception waveform of the concentrator 10, and B schematically illustrates a transmission waveform of the concentrator 10. Further, in FIG. 10, C illustrates a transmission waveform of the first terminal 11, and D illustrates a transmission waveform of the second terminal 12. Note that since the entire configuration of the communication system according to the present embodiment is the same as that according to the first embodiment, and the configuration of the concentrator 10 according to the present embodiment is the same as that according to the second embodiment, descriptions for the present embodiment overlapping with those in the first and the second embodiments will be omitted.

According to the present embodiment, like in the case of the second embodiment, the concentrator 10 transmits a transmission request, as shown by B in FIG. 10, when the reception quality of the first frame is above the predetermined level. Upon receiving the transmission request from the concentrator 10, the second terminal 12 transmits the second frame to the concentrator 10 as shown by D in FIG. 10. As shown by A in FIG. 10, the concentrator 10 receives the second frame from the second terminal 12.

The concentrator 10 carries out the transmission request while receiving the first frame. The concentrator 10 is operable to receive the second frame from the second terminal 12 while receiving the first frame from the first terminal 11 at an appropriate timing. The concentrator 10 is operable to receive and demodulate frames transmitted via different communication methods simultaneously, thereby increasing the network capacity.

### Fourth Embodiment

A communication method according to a present embodiment will be described with reference to FIG. 11. FIG. 11 is a schematic block diagram illustrating a configuration of the concentrator 10, which is a communication device. According to the present embodiment, the concentrator 10 includes, additionally to the configuration of the concentrator 10 according to the second embodiment, a line quality storage unit 41, a first modulation unit 42, a second modulation unit 43, and a synthesis unit 44.

According to the present embodiment, the concentrator 10 includes the first modulation unit 42 and the second modulation unit 43. The first modulation unit 42 modulates transmission data in accordance with the first communication method. The second modulation unit 43 modulates transmission data in accordance with the second communication method. The first modulation unit 42 modules a low rated first frame. The second modulation unit 43 modulates a high rated second frame. The first modulation unit 42 and the second modulation unit 43 modulate data in parallel. That is, the concentrator 10 carries out one modulation process in accordance with the first communication method and another modulation process in accordance with the second communication method in parallel. The first modulation unit 42 outputs the modulated first frame to the synthesis unit 44. The second modulation unit 43 outputs the modulated second frame to the synthesis unit 44.

The reception quality judgment unit 30 outputs reception quality to the line quality storage unit 41. The line quality storage unit 41 is a storage unit such as a memory arranged to store therein judgment outcomes of the reception quality. For example, the line quality storage unit 41 stores therein the reception quality, which is outputted from the reception quality judgment unit 30, as history. That is, the line quality storage unit 41 stores therein the reception quality in a chronological order.

The synthesis unit 44 synthesizes the second frame while transmitting the first frame. Then, the synthesis unit 44 outputs the digital transmission data, which is based on the two synthesized frames, to the DAC 34. The DAC 34 converts the digital transmission data to analog data, and transmits the converted analog transmission data to the AFE 35. The AFE 35 amplifies the digital transmission signal with a predetermined gain, and outputs the amplified signal to the electric power line 13. By such procedure, the first frame and the second frame are respectively transmitted to the first terminal 11 and the second terminal 12 via the electric power line 13.

The synthesis unit 44 synthesizes the first frame and the second frame in accordance with reception quality. The synthesis unit 44 sets a synthesis ratio based on the history of the reception quality retained at the line quality storage unit 41. For example, a ratio of the second frame with respect to the first frame is increased such as to allow the second terminal 12 to demodulate the second frame. That is, an appropriate synthesis ratio is set, based on the reception quality, such as the LQI value, in order to ensure an appropriate CNR to the second terminal 12. The first frame and the second frame are synthesized so that the signal level of the second frame is greater than the signal level of the first frame. For example, the signal level of the second frame is set based on the signal level of the reception quality at which communications were heretofore successfully carried out. Consequently, future communications will be carried out with certainty.

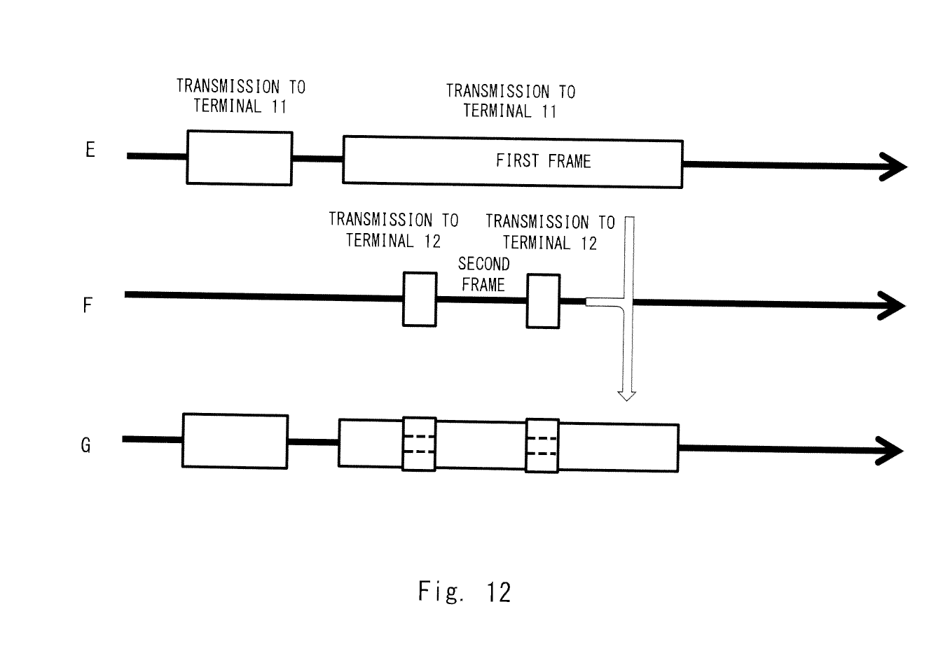

FIG. 12 schematically illustrates a transmission waveform of the concentrator 10. In FIG. 12, E schematically illustrates a transmission waveform of a transmission from the concentrator 10 to the first terminal 11, and F schematically illustrates a transmission waveform of a transmission from the concentrator 10 to the second terminal 12. In FIG. 12, G schematically illustrated a transmission waveform as synthesized by the synthesis unit 44. Note that in FIG. 12, G depicts the signal level of the first frame for a period in which the first frame and the second frame overlap with one another, with a dotted line.

The concentrator 10 transmits the first frame to the first terminal 11. The concentrator 10 transmits the second frame to the second frame intermittently while the first frame being transmitted. The synthesis unit 44 synthesizes the first frame with the second frame and transmits the synthesized frame. That is, the synthesis unit 44 superimposes the second frame on the first frame, and transmits the superimposed frame. The synthesis unit 44 synthesizes the first frame with the second frame in a ratio corresponding to the second frame. Accordingly, the signal level of the first frame is lowered in a period in which the second frame is transmitted compared with a period in which only the first frame is transmitted. That is, while the second frame is superimposed on the first frame, the signal level of the first frame becomes lower than the signal level of the second frame. Further, the signal level of the second frame while the second frame is superimposed on the first frame is at the same level as the signal level of the first frame while the second frame is not superimposed on the first frame.

By virtue of such procedure, the concentrator 10 is operable to transmit the second frame to the second terminal 12 while transmitting the first frame to the first terminal 11. Accordingly, it becomes possible to transmit data to a plurality of terminals simultaneously. Thus, the network capacity is improved.

### Fifth Embodiment

According to the present embodiment, in the reception process carried out by the concentrator 10 according to the first to fourth embodiments, when the second preamble detection unit 26 detects the preamble of the second frame, the AGC 24 sets a gain corresponding to the second frame. Then, when the reception of the second frame is complete, the AGC 24 sets a gain corresponding to the first frame. That is, the gain of PGA 22 set for a period when the first frame and the second frame are received simultaneously is different from the gain of PGA 22 set for a period when only the first frame is received. Note that since the configuration of the concentrator 10 for the present embodiment is the same as that described for the embodiments described above, the depiction thereof will be omitted.

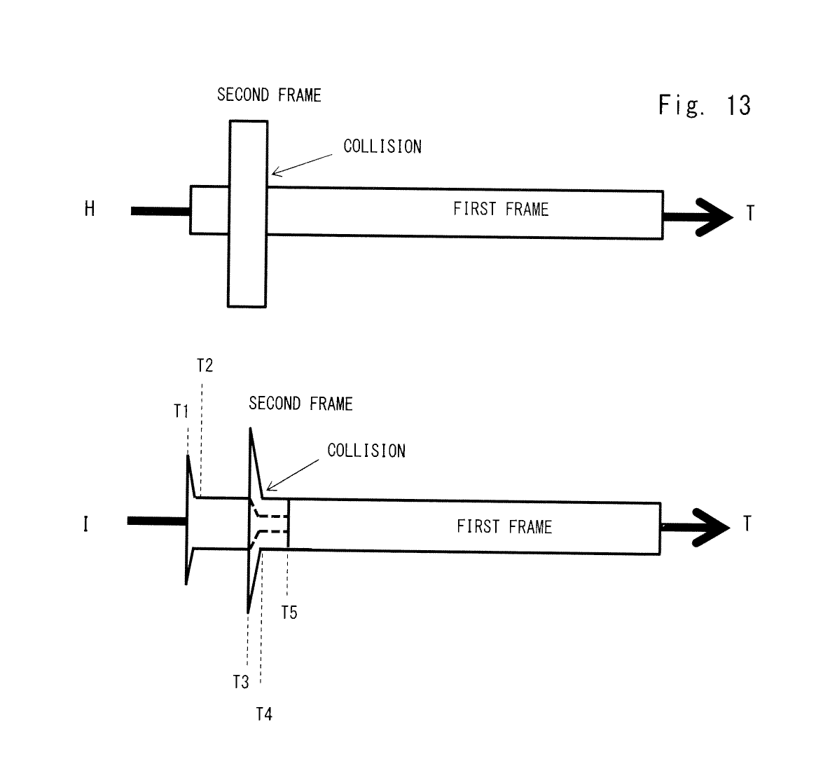

A process carried out according to the present embodiment will be described with reference to FIG. 13. In FIG. 13, H schematically illustrates a waveform of a reception signal received at the concentrator 10, and I schematically illustrates a waveform of the reception signal amplified by the PGA 22. That is, FIG. 13 schematically illustrates an input waveform both before and after the amplification carried out by the PGA 22. A period T1 to T2 depicted in FIG. 13 is a period corresponding to a preamble of the first frame. A period T3 to T4 depicted in FIG. 13 is a period corresponding to a preamble of the second frame. Note that I in FIG. 13 depicts the signal level of the first frame for a period in which the first frame and the second frame overlap with one another, with a dotted line.

When the concentrator 10 receives the first frame, the first preamble detection unit 25 detects a preamble as described above. Then, the first preamble detection unit 25 outputs the detection signal to the AGC 24. The AGC 24 adjusts the gain of the PGA 22. In the period T1 to T2 shown in FIG. 13, the AGC 24 lowers the gain. It is to be noted that the gain, which is suitable to the first frame, will be referred to as a first gain. The PGA 22 amplifies reception signals with the first gain after T2. Accordingly, the signal level of the first frame will be at an appropriate level.

When the concentrator 10 receives the second frame while receiving the first frame, the second preamble detection unit 26 detects the preamble of the second frame. Then, the second preamble detection unit 26 outputs the detection signal to the AGC 24. The AGC 24 sets a gain, which is suitable to the second frame. In the period T3 to T4 shown in FIG. 13, the AGC 24 further lowers the gain. It is to be noted that the gain which is suitable to the second frame, will be referred to as a second gain. The PGA 22 amplifies the receptions signal with the second gain after T4. Accordingly, the signal level of the second frame will be at an appropriate level.

Next, in T5, the reception of the second frame is completed. Then, the AGC 24 adjusts the gain. That is, the AGC 24 returns from the second gain back to the first gain. Accordingly, after T5, the PGA 22 amplifies the reception signal with the first gain. Thus, the signal level of the first frame will be at an appropriate level.

As described above, the gain for the period when the first frame and the second frame are received in an overlapping manner is differentiated from the gain for the period when only the first period is received. Accordingly, each frame is demodulated appropriately.

### Sixth Embodiment

Note that in the first to fifth embodiments described above, the frames, which are collided, may be selected in accordance with the priority of the transmission data. The concentrator 10 selects, in accordance with the priority of the transmission data, the second frame which will be collided with the first frame, and transmits the same. For example, when working with a packet for which timeliness is an important element, the priority of the transmission data will be high. The concentrator 10 transmits the transmission data without waiting for the completion of the reception of the first frame. In another case, the concentrator 10 transmits the transmission request without waiting for the completion of the reception of the first frame. Accordingly, it becomes possible to carry out communications efficiently by increasing the readiness of the system.

### Seventh Embodiment

Note that in the first to sixth embodiments described above, the first frame may include a preamble different from the preamble of the second frame. In a case where the first frame includes a preamble different from a preamble of the second frame, it becomes possible to determine a frame when the first preamble detection unit 25 and the second preamble detection unit 26 each detect a preamble. It thus becomes possible to detect the preamble of the second frame swiftly. Accordingly, it becomes possible to swiftly carry out the transmission of data or transmission requests to the second terminal 12, and the transmission rate can be increased. Further, it is possible to combine the configuration as described for the seventh embodiment with configuration as described for the fifth embodiment in order to detect the preamble of a frame without fail, thereby facilitating the gain adjustment.

Further, a preamble, instead of a header, may include rate information, in order to distinguish the first frame from the second frame solely by the preamble. Accordingly, it becomes possible to transmit the second frame while the first frame being transmitted, thereby improving the transmission rate.

(A First Example of the Configuration of the Reception Quality Judgment Unit)

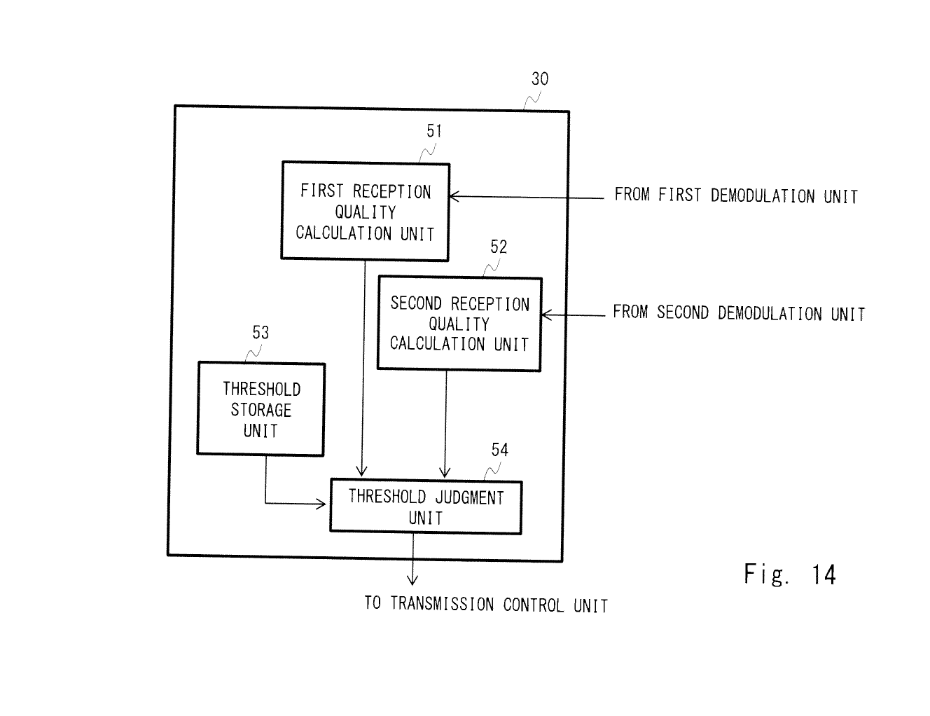

Next, an example of the reception quality judgment unit 30, which is used in the first to seventh embodiments, will be described. FIG. 14 is a schematic block diagram illustrating the example of the reception quality judgment unit 30. The reception quality judgment unit 30 includes a first reception quality calculation unit 51, a second reception quality calculation unit 52, a threshold storage unit 53, and a threshold judgment unit 54.

The first demodulated data is inputted to the reception quality judgment unit 30 from the first demodulation unit 27. The first reception quality calculation unit 51 calculates a first reception quality based on the first demodulation data. The first reception quality is an index indicating the reception quality of the first communication method, and is, for example, the LQI value. The second demodulated data is inputted to the reception quality judgment unit 30 from the second demodulation unit 28. A second reception quality is an index indicating the reception quality of the second communication method, and is, for example, the LQI value.

The threshold storage unit 53 is a storage unit, such as a memory, arranged to store therein a threshold, which corresponds to a lowest reception quality. The lowest reception quality is a value indicating a lowest communication quality level at which the demodulation process is carried out. The threshold is a value obtained by adding a margin (for example, 10 dB) to the lowest reception quality. The threshold judgment unit 54 compares the threshold with reception quality. The threshold judgment unit 54 outputs a comparison signal corresponding to the comparison outcome to the transmission control unit 32. When the reception quality of the first communication method is above the threshold, the transmission control unit 32 permits a transmission. When the reception quality of the first communication method is below the threshold, the transmission control unit 32 suspends a transmission. Accordingly, the concentrator 10 is operable to carry out the transmission of data or the transmission request at an appropriate timing. That is, the second terminal 12 is operable to receive and demodulate the second frame.

(A Second Example of the Configuration of the Reception Quality Judgment Unit)

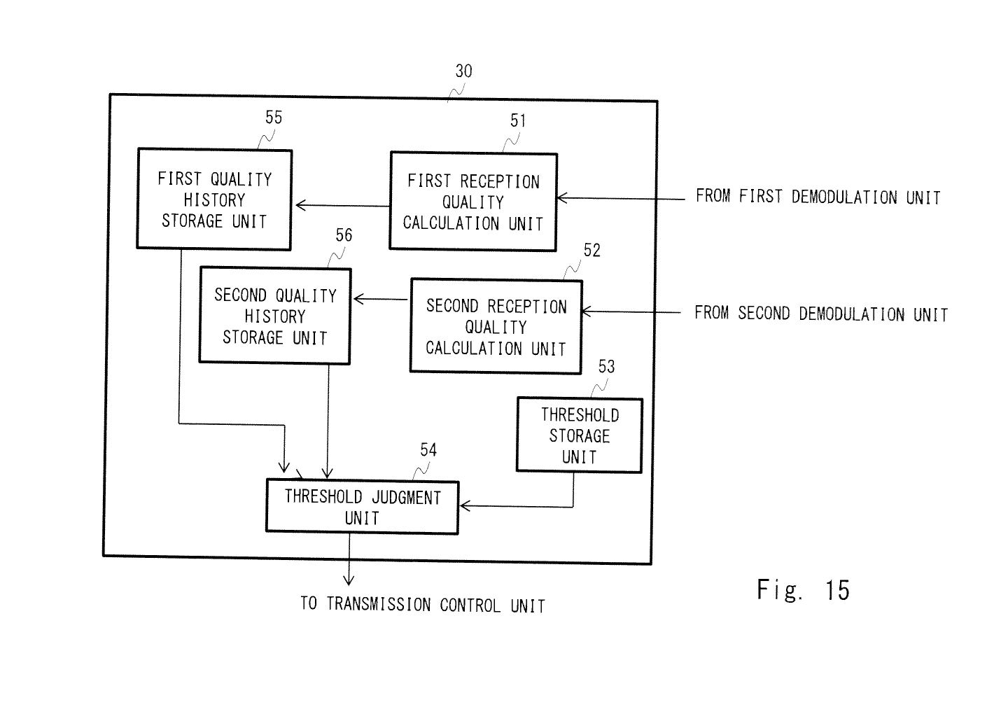

Another example of the reception quality judgment unit 30, which is used in the first to seventh embodiments, will be described. FIG. 15 is a schematic block diagram illustrating the example of the reception quality judgment unit 30. The reception quality judgment unit 30 includes, additionally to the configuration of the reception quality judgment unit 30 shown in FIG. 14, a first quality history storage unit 55, and a second quality history storage unit 56. Note that the descriptions for the first reception quality calculation unit 51, the second reception quality calculation unit 52, the threshold storage unit 53, and the threshold judgment unit 54 which overlap with the configuration shown in FIG. 14 will be omitted. According to FIG. 15, it is determined, by utilizing the history of reception quality, whether or not to transmit data by the second communication method.

The first quality history storage unit 55 is a storage unit, such as a memory, or the like, arranged to store therein a history of the reception quality of the first communication method. The second quality history storage unit 56 is a storage unit, such as a memory, or the like, arranged to store therein a history of the reception quality of the second communication method. Accordingly, the first quality history storage unit 55 and the second quality history storage unit 56 each store therein communication qualities.

The threshold judgment unit 54 compares information corresponding to the history of the reception quality of the first communication method with the threshold. The information corresponding to the history of the reception quality may be, for example, an average of reception quality. To be more specific, a moving average or a short term moving average, or the like, may be used for the history of the reception quality. Further, a temporally weighted average may be used for the history of the reception quality. As described above, the threshold judgment unit 54 compares the value corresponding to the history of reception quality and the threshold. Further, the threshold judgment unit 54 outputs the comparison signal corresponding to the comparison outcome to the transmission control unit 32.

When the average value of the reception quality of the first communication method is above the threshold, the transmission control unit 32 permits a transmission. When the average value of the reception quality of the first communication method is below the threshold, the transmission control unit 32 suspends a transmission. Accordingly, the concentrator 10 is operable to carry out the transmission of data or the transmission request at an appropriate timing. That is, the second terminal 12 is operable to receive and demodulate the second frame.

(A Third Example of the Configuration of the Reception Quality Judgment Unit)

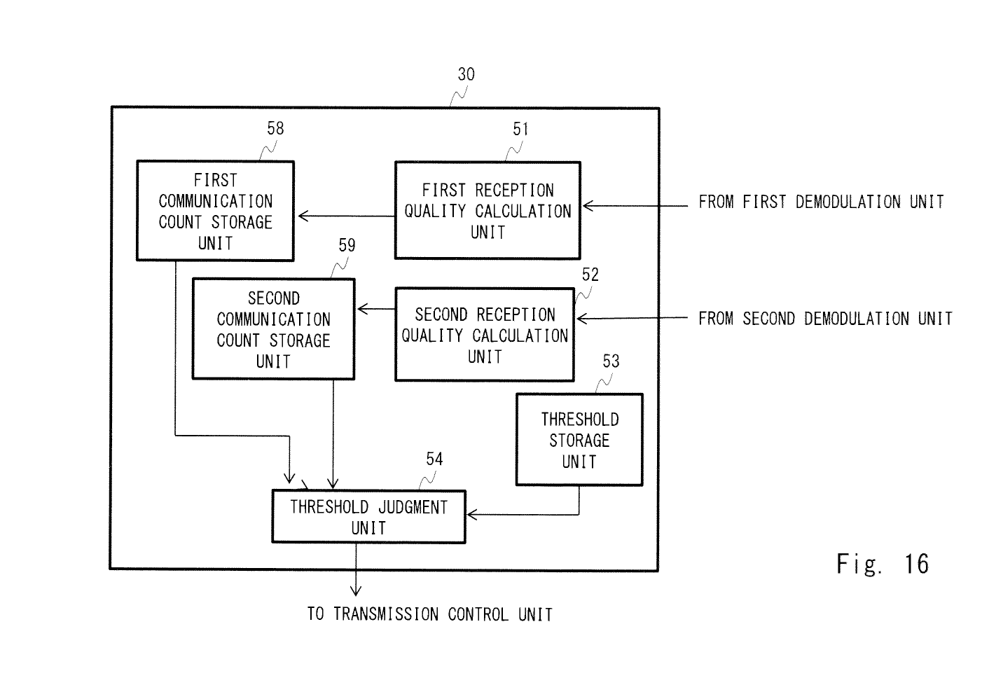

Another example of the reception quality judgment unit 30, which is used in the first to seventh embodiments, will be described. FIG. 16 is a schematic block diagram illustrating the example of the reception quality judgment unit 30. The reception quality judgment unit 30 includes a first communication count storage unit 58 and a second communication count storage unit 59 to respectively replace the first quality history storage unit 55 and the second quality history storage unit 56. Note that the descriptions for the first reception quality calculation unit 51, the second reception quality calculation unit 52, the threshold storage unit 53, and the threshold judgment unit 54 which overlap with the configurations shown in FIGS. 14 and 15 will be omitted. According to the configuration shown in FIG. 16, reception quality is judged according to the number of times (i.e., count) the first frame and the second frame are communicated. That is, it is determined whether or not to transmit data by the second communication method based on the number of times the frames are communicated. For example, when the number of collisions of the second frame per one first frame is increased, the communication quality is lowered.

The first communication count storage unit 58 stores therein the number of times the first frame is communicated. The second communication count storage unit 59 stores therein the number of times the second frame is communicated. The first communication count storage unit 58 and the second communication count storage unit 59 each store therein the number of times the respective frame is communicated. The threshold storage unit 53 stores therein a threshold corresponding to a permissible collision number. The permissible collision number corresponds to a permissible value for the number of times the second frame is demodulated during the reception of the first frame. For example, when it is possible to transmit the second frame 10 times with respect to the robust first frame, the threshold is 10. Then, the threshold judgment unit 54 compares, in the same manner as described above, the number of times of communication with the threshold, and outputs the comparison signal to the transmission control unit 32. The threshold judgment unit 54 compares the number of times communications are carried out with the threshold, and judges the reception quality. The threshold judgment unit 54 judges that the reception quality is low when the number of the second frames received while receiving the first frame is greater than the threshold, and judges that the reception quality is high when said number is below the threshold.

When the number of times collisions occur is below the threshold, the transmission control unit 32 permits a transmission. When the number of times collisions occur is above the threshold, the transmission control unit 32 suspends a transmission. Accordingly, the concentrator 10 is operable to carry out the transmission of data or the transmission request at an appropriate timing. That is, the second terminal 12 is operable to receive and demodulate the second frame.

Further, the reception quality judgment unit 30 as shown in FIGS. 14 to 16, may be able to change the number of times collisions occur for a frame in accordance with the judgment outcome. For example, when reception quality is adequately high, the transmission rate may be further raised. Consequently, the transmission frequency of the second frame is increased. That is, the number of the second frames transmitted during the reception of the first frame is increased. Accordingly, by changing the number of times collisions occur for a frame in accordance with reception quality, the transmission rate may be further increased. That is, when reception quality is adequately high, the number of times collisions occur for a frame may be increased. On the contrary, when reception quality is not adequately high compared to the lowest reception quality, the number of times collisions occur for a frame is minimized thereby improving the reception quality. Further, depending on the comparison outcome, the degree of redundancy may be changed. That is, when reception quality is adequately high, the redundancy is lowered so as to shorten the length of the first frame. Consequently, the transmission rate will be improved.

An example of a procedure to determine a frame length will be described. For example, the concentrator 10 transmits a transmission request to the first terminal 11. Upon receiving the transmission request, the first terminal 11 transmits the frame, whose length is determined by the redundancy and/or the transmission speed, or the like, to the concentrator 10. When the concentrator 10 is unable to demodulate the frame, the concentrator 10 transmits another transmission request to the first terminal 11. The first terminal 11 extends, by either increasing the redundancy or lowering the transmission speed, the frame length so that the frame length is longer than the previous one, and transmits the extended frame. By repeating such process, the frame length, which is suited for the transmission, is determined. That is, when a frame is not demodulated, the frame is made more robust and the length thereof is made suited for reception. The same procedure regarding the determination of the frame length is carried out with respect to the second terminal 12. It is to be noted that the procedure to determine the frame length is not limited to the procedure described above. For example, when the concentrator 10 is able to demodulate a frame, the frame length of the next frame may be shortened by lowering the redundancy or increasing the transmission speed.

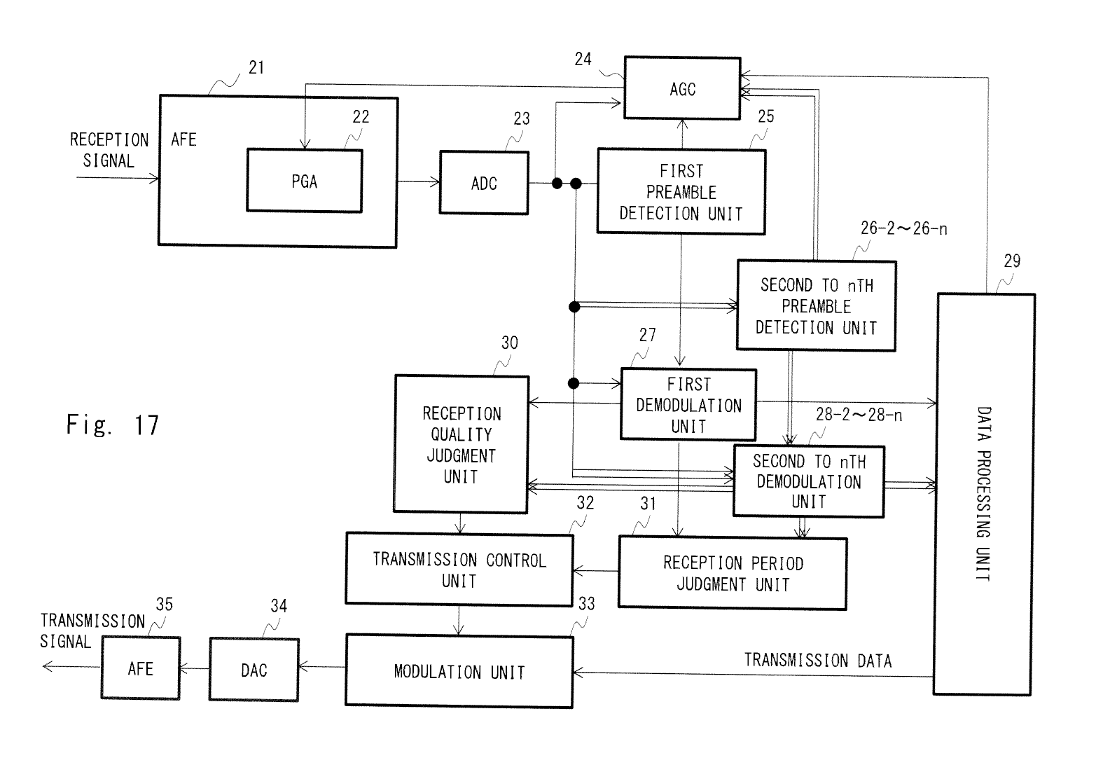

Note that although the examples using the two communication methods are described in the ongoing description, three or more communication methods may be used. When more than three communication methods are used, the preamble detection unit and the demodulation unit are arranged for each communication method as shown in FIG. 17. For example, when n number of communication methods are used, the first preamble detection unit 25 and the second preamble detection unit 26-2 to n-th preamble detection unit 26-nth (n is an integer greater than or equal to 3) are arranged, and the first demodulation unit 27 and the second demodulation unit 28-2 to nth demodulation unit 28-nth are arranged. Then, the first preamble detection unit 25 and the second to nth preamble detection units 26-2 to 26-nth each detect a preamble of a frame in accordance with its corresponding communication method. The first preamble detection unit 25 and the second to nth preamble detection units 26-2 to 26-nth are operable to detect the preamble in parallel.

After the preamble is detected, the first demodulation unit 27 and the second to nth demodulation units 28-2 to 28-nth each carry out the modulation process in accordance with the communication method corresponding thereto. The first demodulation unit 27 and the second to nth demodulation units 28-2 to 28-nth each are operable to carry out the demodulation process in parallel. Accordingly, when more than n number of frames are simultaneously collided and received in parallel, the CNR of n−1 (n minus 1) frames is less than 0 dB, meaning that only one frame will have its CNR greater than 0 dB. For example, when the second demodulation unit 28-2 communicates with a communication method whose CNR is equal to or greater than 0 dB (i.e., CNR is equal to or greater than 0), other demodulation units will carry out their transmission with a communication method whose CNR is smaller than 0 dB (i.e., CNR<0 dB). While receiving a plurality of frames each of whose CNR is smaller than 0 dB, one frame whose CNR is greater than 0 dB is received. Accordingly, it becomes possible to communicate with more than 3 terminals in parallel.

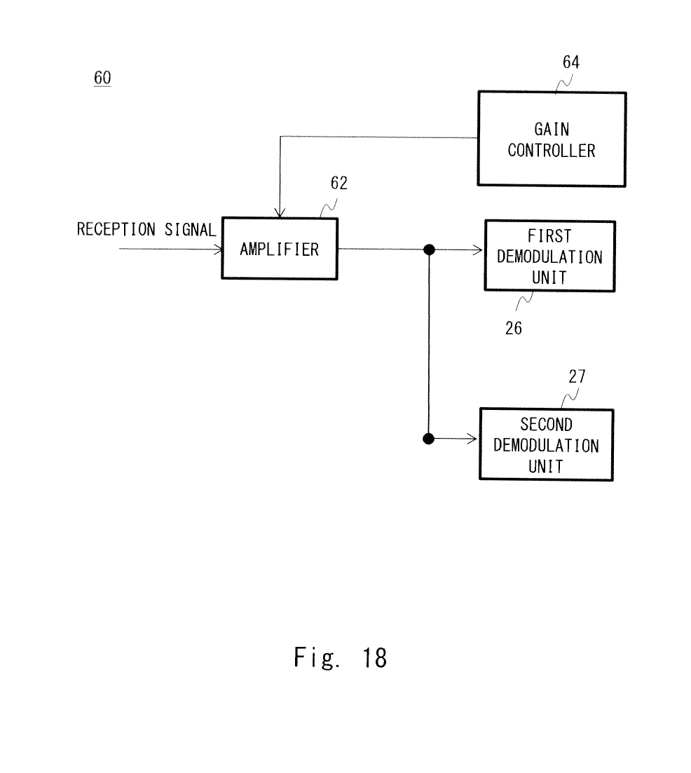

Note that the communication device according to the present embodiment may include a configuration as shown in FIG. 18. A communication device 60 includes an amplifier 62, a gain controller 64, the first demodulation unit 27, and the second demodulation unit 28. As described above, the first demodulation unit 27 demodulates the first frame, and the second demodulation unit 28 demodulates the second frame. The amplifier 62 corresponds to the PGA 22, and the gain controller 64 corresponds to the AGC 24.

The communication device 60 carries out a communication with a plurality of terminals in the same manner as described above. The amplifier 62 amplifies the reception signal received from the terminal. The first demodulation unit 27 demodulates the first frame which is transmitted by the first communication method operable to communicate when the CNR is lesser than 0 dB. The second demodulation unit 28 demodulates, in parallel with the demodulation carried out by the first demodulation unit 27, the second frame, which is transmitted by the second communication method, using a frequency band the same as that for the first communication method, and whose rate is higher than that for the first communication method. The gain controller 64 adjusts the gain of the amplifier 62 in accordance with the detection outcome of the preamble included in the first frame and the second frame. Such configuration is operable to achieve the same effect as the configurations previously described above.

Although the present description describes PLC (Power Line Communication) using the electric power line 13a, the communication method used for the above described embodiments is not limited thereto. For example, the present invention may be used for a communication device using a wireless such as ZigBee, or the like. Further, the present invention may be used for a cable communication using a cable other than the electric power line 13. It is to be noted that the above described the first to seventh embodiments may be combined in any suitable manner in one or more alternatives. That is, a combination of more than two of the embodiments described above may be used.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A communication device arranged to communicate with a plurality of terminals, the communication device comprising:
an amplifier arranged to amplify a reception signal received from one of the plurality of terminals;
a first demodulation unit arranged to demodulate a first frame transmitted using a first communication method operable to communicate when CNR is smaller than 0 dB;
a second demodulation unit arranged to demodulate, in parallel with the first demodulation unit demodulating the first frame, a second frame transmitted using a second communication method having a rate higher than a rate of the first communication method at a frequency band same as a frequency band used for the first communication method; and
a gain controller arranged to adjust a gain of the amplifier in accordance with a detection outcome of a preamble included in the first frame and the second frame.

2. The communication device according to claim 1 further comprising a reception quality judgment unit arranged to judge reception quality of the first frame, wherein
the communication device transmits data when the reception quality judgment unit judges that reception quality of the first frame in a reception period of the first frame is above a predetermined level.

3. The communication device according to claim 2 wherein the communication device transmits, when the reception quality judgment unit judges that reception quality of the first frame in the reception period of the first frame is above the predetermined level, a transmission request of the second frame to a second terminal requesting.

4. The communication device according to claim 3 wherein the communication device transmits the transmission request of the second frame to the second terminal while the communication device receives the first frame transmitted by the first terminal.

5. The communication device according to claim 2, the communication device further comprising:
a first modulation unit arranged to generate a first transmission frame by modulating transmission data in accordance with the first communication method;
a second modulation unit arranged to generate a second transmission frame by modulating transmission data in accordance with the second communication method; and
a synthesis unit arranged to synthesize the first transmission frame and the second transmission frame for transmission.

6. The communication device according to claim 5 wherein the synthesis unit modifies a synthesis ratio of the second transmission frame with respect to the first transmission frame in accordance with the reception quality of the first frame.

7. The communication device according to claim 1 wherein the first frame includes a preamble different from a preamble included in the second frame.

8. The communication device according to claim 2 wherein the communication device modifies a number of times the second frame is collided with the first frame in accordance with the reception quality.

9. The communication device according to claim 1 wherein the communication device selects, in accordance with a priority of communication data, the second frame collided with the first frame, and transmits the second frame.

10. A communication system comprising:
the communication device according to claim 1; and
a plurality of terminals connected to the communication device via an electric power line.

11. A communication method, comprising:
amplifying a reception signal received from a first terminal;
demodulating a first frame, transmitted using a first communication method operable to communicate when CNR is smaller than 0 dB;
demodulating a second frame in parallel with the first frame demodulated, the second frame being transmitted using a second communication method having a rate higher than a rate of the first communication method at a frequency band same as a frequency band used for the first communication method; and
adjusting a gain in accordance with a detection outcome of a preamble included in the first frame and the second frame.

12. The communication method according to claim 11 further comprising:
judging reception quality of the first frame, and
transmitting data when the reception quality of the first frame in a reception period of the first frame is above a predetermined level.

13. The communication method according to claim 12, wherein a transmission request of the second frame is transmitted to a second terminal when the reception quality of the first frame in the reception period of the first frame is above the predetermined level.

14. The communication method according to claim 13 wherein the transmission request of the second frame transmitted to the second terminal during receiving the first frame transmitted by the first terminal.

15. The communication method according to claim 12, further comprising:
generating a first transmission frame by modulating transmission data in accordance with the first communication method;
generating a second transmission frame by modulating transmission data in accordance with the second communication method; and
synthesizing the first transmission frame and the second transmission frame for transmission.

16. The communication method according to claim 15 wherein a synthesis ratio of the second transmission frame with respect to the first transmission frame is modified in accordance with the reception quality of the first frame.

17. The communication method according to claim 11 wherein the first frame includes a preamble different from a preamble included in the second frame.

18. The communication method according to claim 12 wherein a number of times the second frame is collided to the first frame is modified in accordance with the reception quality.

19. The communication method according to claim 11 wherein the second frame collided to the first frame is selected in accordance with a priority of communication data, and is transmitted.
